(19) United States
(12) Patent Application Publication
(10) Pub. No.: US 2025/0324821 A1
(43) Pub. Date: Oct. 16, 2025

(54) LIGHT-EMITTING DEVICE

(71) Applicant: NICHIA CORPORATION, Anan-shi (JP)

(72) Inventors: Yusuke HAYASHI, Anan-shi (JP); Satoshi SHICHIJO, Tokushima-shi (JP)

(21) Appl. No.: 19/251,139

(22) Filed: Jun. 26, 2025

Related U.S. Application Data
(63) Continuation of application No. PCT/JP2023/046209, filed on Dec. 22, 2023.

(30) Foreign Application Priority Data
Dec. 27, 2022 (JP) 2022-210850

(51) Int. Cl. H10H 20/813; H10H 20/851; H10H 20/855

(52) U.S. Cl. CPC H10H 20/8132; H10H 20/8515; H10H 20/855

(57) ABSTRACT

A light-emitting device includes a first region and a second region configured to emit lights with different luminances when the light-emitting device is turned on, in which luminance La of the first region is higher than luminance Lb of the second region. When an emission spectrum of light emitted from the first region has a maximum intensity Iaₘₐₓ in a wavelength range of 400 nm to 500 nm, an intensity Ia₅₀₇ at a wavelength of 507 nm, and an intensity Ia₅₅₅ at a wavelength of 555 nm, an emission spectrum of light emitted from the second region has an intensity Ib₅₀₇ at a wavelength of 507 nm, and an intensity Ib₅₅₅ at a wavelength of 555 nm, and relative intensities Ira₅₀₇, Ira₅₅₅, Irb₅₀₇, and Irb₅₅₅ are obtained by respectively dividing Ia₅₀₇, Ia₅₅₅, Ib₅₀₇, and Ib₅₅₅ by Iaₘₐₓ, Ira₅₀₇ is lower than Irb₅₀₇, and Ira₅₅₅ is higher than Irb₅₅₅.

### CROSS-REFERENCE TO RELATED APPLICATIONS

This is a bypass continuation of PCT Application No. PCT/JP2023/046209, filed on Dec. 22, 2023, which claims priority to Japanese Patent Application No. 2022-210850, filed on Dec. 27, 2022. The disclosures of these applications are hereby incorporated herein by reference in their entireties.

### BACKGROUND

### Technical Field

The present disclosure relates to a light-emitting device.

### Background Art

In recent years, LEDs have been used as light sources for vehicle lamps such as headlights. For example, Japanese Patent Application Publication No. 2017-011259 A discloses a light-emitting device comprising a combination of multiple light-emitting elements with varying areas, thereby achieving a light distribution suitable for a headlight.

### SUMMARY

An object of the present disclosure is to provide a light-emitting device including a high luminance region and a low luminance region in a light-emitting surface and having high visibility in each of the regions.

A light-emitting device according to certain embodiments of the present disclosure includes: a first region and a second region configured to emit light with different luminances when the light-emitting device is turned on, in which luminance La of the first region is higher than luminance Lb of the second region, an emission spectrum of light emitted from the first region has a maximum intensity Iaₘₐₓ in a wavelength range of 400 nm to 500 nm, an intensity Ia₅₀₇ at a wavelength of 507 nm, and an intensity Ia₅₅₅ at a wavelength of 555 nm, an emission spectrum of light emitted from the second region has an intensity Ib₅₀₇ at a wavelength of 507 nm, and an intensity Ib₅₅₅ at a wavelength of 555 nm, and relative intensities Ira₅₀₇, Ira₅₅₅, Irb₅₀₇, and Irb₅₅₅ are obtained by respectively dividing the intensities Ia₅₀₇, Ia₅₅₅, Ib₅₀₇, and Ib₅₅₅ by the maximum intensity Iaₘₐₓ, the relative intensity Ira₅₀₇ is lower than the relative intensity Irb₅₀₇, and the relative intensity Ira₅₅₅ is higher than the relative intensity Irb₅₅₅.

A light-emitting device according to an embodiment of the present disclosure includes a high luminance region and a low luminance region in a light-emitting surface and has high visibility in each of the regions.

### BRIEF DESCRIPTION OF DRAWINGS

FIG. 1 is a plan view schematically illustrating an example of a light-emitting device according to a first embodiment.

FIG. 2 is a graph showing first and second emission spectra and a luminous efficiency curve of the light-emitting device according to the first embodiment.

FIG. 3 is a cross-sectional view schematically illustrating an example of the light-emitting device according to the first embodiment.

FIG. 4 is a cross-sectional view schematically illustrating a modified example of the light-emitting device according to the first embodiment.

FIG. 5 is a cross-sectional view schematically illustrating an example of a method of manufacturing the light-emitting device according to the first embodiment.

FIG. 6A is a plan view schematically illustrating an example of the method of manufacturing the light-emitting device according to the first embodiment.

FIG. 6B is a schematic cross-sectional view taken along line A-A in FIG. 6A.

FIG. 7A is a plan view schematically illustrating an example of the method of manufacturing the light-emitting device according to the first embodiment.

FIG. 7B is a schematic cross-sectional view taken along line B-B in FIG. 7A.

FIG. 8A is a plan view schematically illustrating an example of the method of manufacturing the light-emitting device according to the first embodiment.

FIG. 8B is a schematic cross-sectional view taken along line C-C in FIG. 8A.

FIG. 9A is a plan view schematically illustrating an example of the method of manufacturing the light-emitting device according to the first embodiment.

FIG. 9B is a schematic cross-sectional view taken along line D-D in FIG. 9A.

FIG. 10 is a plan view schematically illustrating an example of a light-emitting device according to a second embodiment.

FIG. 11 is a cross-sectional view schematically illustrating an example of the light-emitting device according to the second embodiment.

FIG. 12 is a cross-sectional view schematically illustrating an example of the light-emitting device according to the second embodiment.

FIG. 13 is a cross-sectional view schematically illustrating an example of the light-emitting device according to the second embodiment.

FIG. 14 is a cross-sectional view schematically illustrating an example of the light-emitting device according to the second embodiment.

FIG. 15 is a cross-sectional view schematically illustrating an example of a light-emitting device according to a third embodiment.

FIG. 16 is a cross-sectional view schematically illustrating an example of the light-emitting device according to the third embodiment.

FIG. 17 is a cross-sectional view schematically illustrating an example of a light-emitting device according to a fourth embodiment.

FIG. 18 is a graph showing first and second emission spectra and a luminous efficiency curve of the light-emitting device according to the fourth embodiment.

### DETAILED DESCRIPTION

In the light distribution of a headlight, it is desirable that the illuminance is high in the central portion of the irradiation surface, and the illuminance decreases as the distance from the center increases. As a countermeasure, the present inventors have studied a light-emitting device in which the luminance of the light-emitting surface is partially high (this light-emitting device is referred to as a “partially high luminance light-emitting device”). The partially high luminance light-emitting device is provided with a low luminance region and a high luminance region by reducing luminance in a partial region of the light-emitting surface. In the partially high luminance light-emitting device, light emitted from the high luminance region and light emitted from the low luminance region have substantially the same emission spectra.

As a result of studies to further improve the performance of the partially high luminance light-emitting device, the present inventors have conceived of a possibility that the visibility is different between the light emission from the high luminance region and the light emission from the low luminance region. It is presumable that mesopic vision to photopic vision is obtained for light emission from the high luminance region, and scotopic vision to mesopic vision is obtained for light emission from the low luminance region.

In view of the above, the present inventors have conducted intensive studies in order to provide a partially high luminance light-emitting device in which visibility is improved for both light emission from the high luminance region and light emission from the low luminance region, and have completed the light-emitting device according to an embodiment of the present invention.

Embodiments will be described below with reference to the drawings. The configurations described below are examples of light-emitting devices and methods of manufacturing the light-emitting devices to embody the technical idea of the present embodiment, and the present embodiment is not limited to the embodiments described below. Unless otherwise specified, dimensions, materials, shapes, relative arrangements, or the like of components described in the embodiments are not intended to limit the scope of the present invention thereto and are merely examples. Sizes, positional relationships, and the like of members illustrated in the drawings may be exaggerated or simplified for clarity of description. To avoid overcomplicating the drawings, some elements may be omitted or end views illustrating only cut surfaces may be used as cross-sectional views. As used herein, the term “cover, covering” is not limited to cases of direct contact, but also includes cases of indirectly covering a member, for example, via another member. Furthermore, “disposing” includes not only a case of disposing by direct contact but also a case of indirectly disposing, for example, via another member. As used herein, the term “plan view” refers to a view from the light-emitting surface side of the light-emitting device.

### First Embodiment

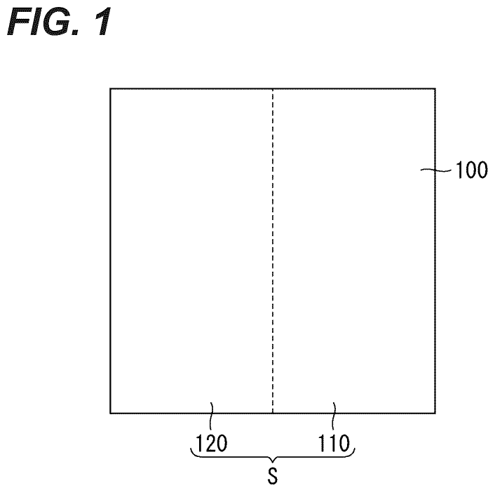

FIG. 1 is a plan view of a light-emitting device 100 according to a first embodiment.

When viewed from the light-emitting surface S side, the light-emitting device 100 includes a first region 110 and a second region 120 that emit light with different luminances when the light-emitting device 100 is turned on.

Luminance La of the first region 110 is higher than luminance Lb of the second region 120. That is, a relationship of “La>Lb” is satisfied. In the present specification, the first region 110 and the second region 120 may be referred to as a “high luminance region 110” and a “low luminance region 120”, respectively.

In the present specification, the “high luminance region 110” is a region constituted by a portion having luminance of 80% or more and 100% or less of the highest luminance (referred to as a maximum luminance Laₘₐₓ) in the light-emitting device 100, and the “low luminance region 120” is a region constituted by a portion having luminance of 5% or more and less than 80% of the maximum luminance Laₘₐₓ.

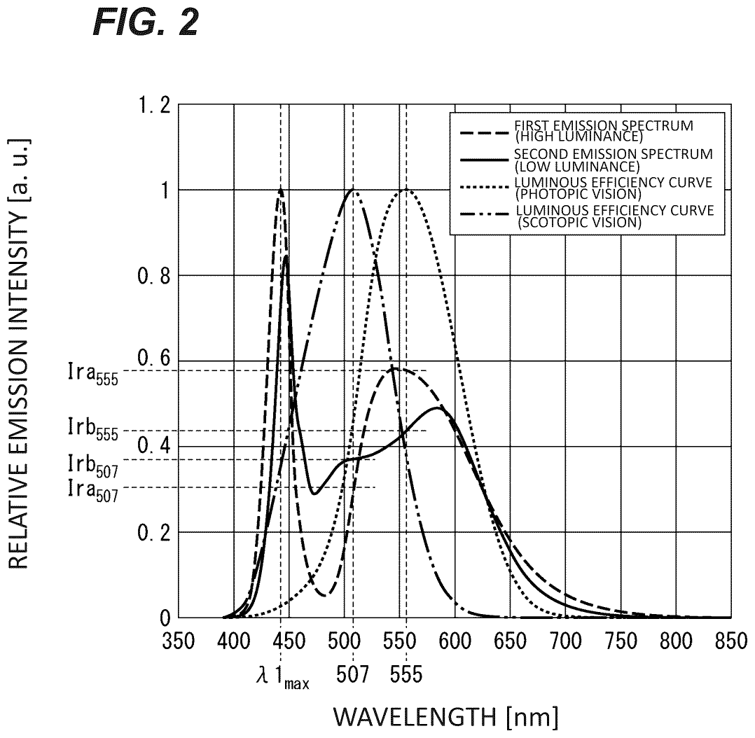

FIG. 2 is a graph showing emission spectra. An emission spectrum of light emitted from the first region (high luminance region) 110 of the light-emitting device 100 (referred to as a “first emission spectrum”) and an emission spectrum of light emitted from the second region (low luminance region) 120 of the light-emitting device 100 (referred to as a “second emission spectrum”) are shown. These emission spectra are obtained by individually measuring the emission spectra of the light emitted from the high luminance region 110 and the light emitted from the low luminance region 120. As an example of a method of measuring the emission spectrum of the light emitted from each region, there is a method of measuring the emission spectrum in a state where a region other than the region to be measured in the light-emitting surface S of the light-emitting device 100 is covered with a material (mask) that absorbs light. According to this method, only the emission spectrum of the light emitted from the region to be measured can be measured. Note that in a case in which the luminance measurement device has a function of individually measuring the emission spectrum of light emitted from each region, the luminance and the emission spectrum of light emitted from each region can be measured without using a mask.

The emission spectrum of the light-emitting device 100 is the sum of the first emission spectrum and the second emission spectrum.

The first emission spectrum has a maximum intensity Iaₘₐₓ in a wavelength range of 400 nm to 500 nm, an intensity Ia₅₀₇ at a wavelength of 507 nm, and an intensity Ia₅₅₅ at a wavelength of 555 nm. In the first emission spectrum shown in FIG. 2, the maximum intensity Iaₘₐₓ is the intensity at a wavelength λ1ₘₐₓ.

The second emission spectrum has an intensity Ib₅₀₇ at a wavelength of 507 nm and an intensity Ib₅₅₅ at a wavelength of 555 nm.

In order to compare intensities (emission intensities), the relative intensities of emission intensities are obtained with the relative intensity of the maximum intensity Iaₘₐₓ set to 1. That is, the intensities Ia₅₀₇, Ia₅₅₅, Ib₅₀₇, and Ib₅₅₅ are divided by the maximum intensity Iaₘₐₓ to obtain the relative intensities (relative emission intensities) Ira₅₀₇, Ira₅₅₅, Irb₅₀₇, and Irb₅₅₅. The relationship between these relative intensities is such that the relative intensity Ira₅₀₇ is lower than Irb₅₀₇. That is, the relationship of “Ira₅₀₇<Irb₅₀₇” is satisfied. In addition, the relative intensity Ira₅₅₅ is higher than Irb₅₅₅. That is, the relationship of “Ira₅₅₅>Irb₅₅₅” is satisfied.

It is presumable that light emission from the high luminance region 110 is perceived as “photopic vision” and light emission from the low luminance region 120 is perceived as “scotopic vision” by human eyes. As shown in FIG. 2, the luminous efficiency curve of human eyes differs between the photopic vision and the scotopic vision. In order to improve visibility in the photopic vision, it is effective to perform illumination with light having a high emission intensity at 555 nm, which is the peak wavelength of the luminous efficiency curve of the photopic vision. Similarly, in order to improve visibility in the scotopic vision, it is effective to perform illumination with light having a high emission intensity at 507 nm, which is the peak wavelength of the luminous efficiency curve of the scotopic vision.

In the light-emitting device 100 according to the first embodiment, the light from the high luminance region 110 has a relative intensity at a wavelength of 555 nm higher than a relative intensity of the light from the low luminance region 120, and thus has a higher photopic relative luminous efficiency. On the other hand, the light from the low luminance region 120 has a relative intensity at a wavelength of 507 nm higher than a relative intensity of the light from the high luminance region 110, and thus has a higher scotopic relative luminous efficiency. Therefore, in the light-emitting device 100, both the light from the high luminance region 110 and the light from the low luminance region 120 have high visibility.

In FIG. 1, a boundary between the high luminance region 110 and the low luminance region 120 is illustrated as being parallel to a side of the outer periphery of the light-emitting device 100. However, the shape of the boundary is not limited thereto, and the boundary can be modified into any shape so as to achieve a desired light distribution. For example, the boundary between the high luminance region 110 and the low luminance region 120 may be inclined with respect to a side of the outer periphery of the light-emitting device 100 in a plan view. In addition, the boundary between the high luminance region 110 and the low luminance region 120 is not limited to a straight line in a plan view, and may be a curved line. Further, the area ratio of the high luminance region 110 and the low luminance region 120 on the light-emitting surface S side of the light-emitting device 100 can also be appropriately changed in accordance with the intended use.

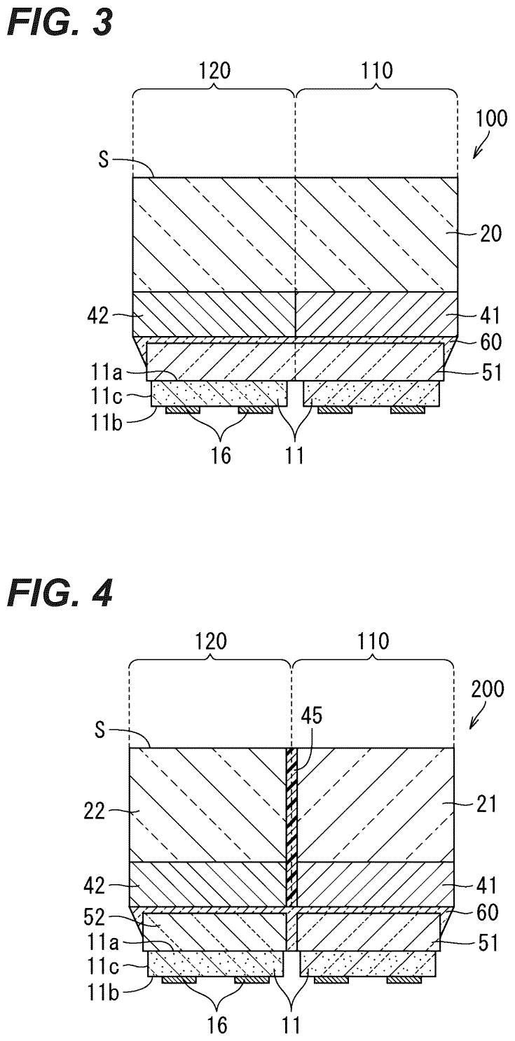

A specific configuration example of the light-emitting device 100 is illustrated in FIG. 3.

The light-emitting device 100 includes a first light-emitting layer 11 having an emission peak in a wavelength range of 400 nm to 500 nm, and at least two wavelength conversion members (a first wavelength conversion member 41 and a second wavelength conversion member 42) that convert a wavelength of light emitted from the first light-emitting layer 11.

The first light-emitting layer 11 includes an electrode-formed surface 11b on which electrodes 16 are formed, a light extraction surface 11a located opposite to the electrode-formed surface 11b, and a plurality of lateral surfaces 11c connecting the electrode-formed surface 11b and the light extraction surface 11a. The light from the first light-emitting layer 11 can be emitted not only from the light extraction surface 11a but also from the lateral surfaces 11c.

The wavelength conversion members (the first wavelength conversion member 41 and the second wavelength conversion member 42) are disposed on the light extraction surface 11a side of the first light-emitting layer 11.

In the present specification, the “light-emitting layer” refers to a layer-form body that is composed of a single layer or multiple layers and emits light when electricity is supplied thereto. The light-emitting layer is, for example, a semiconductor layered body in which a plurality of semiconductor layers are layered.

When viewed from the light-emitting surface S side of the light-emitting device 100, the first wavelength conversion member 41 is disposed in the first region (high luminance region) 110, and the second wavelength conversion member 42 is disposed in the second region (low luminance region) 120. The peak wavelength of the light that has been subjected to wavelength conversion by the first wavelength conversion member 41 is longer than the peak wavelength of the light that has been subjected to wavelength conversion by the second wavelength conversion member 42.

That is, the light from the high luminance region 110 includes light that is a part of the light from the first light-emitting layer 11 and shifted to the longer-wavelength side by the first wavelength conversion member 41, and thus has a relatively high emission intensity on the long-wavelength side (at a wavelength of 555 nm). Although the light from the low luminance region 120 includes light that is a part of the light from the first light-emitting layer 11 and shifted to the longer-wavelength side by the second wavelength conversion member 42, the shift amount by the second wavelength conversion member 42 is small, so that its emission intensity on the short-wavelength side (at a wavelength of 507 nm) is relatively high.

With such a configuration, it is possible to form the light-emitting device 100 in which the photopic relative luminous efficiency of the light from the high luminance region 110 is high and the scotopic relative luminous efficiency of the light from the low luminance region 120 is also high.

The light-emitting device 100 includes a plurality of the first light-emitting layers 11 in the example illustrated in FIG. 3. In this case, the current value can be changed for each first light-emitting layer 11.

In a case in which the light-emitting device 100 includes the plurality of first light-emitting layers 11, the plurality of first light-emitting layers 11 are arranged laterally so as not to overlap each other when viewed from the light-emitting surface S side of the light-emitting device 100. In particular, as illustrated in FIG. 3, it is preferable that the light extraction surfaces 11a of the plurality of first light-emitting layers 11 are disposed so as to be flush with each other. At least one first light-emitting layer 11 is preferably disposed in each of the first region 110 and the second region 120 when viewed from the light-emitting surface S side of the light-emitting device 100. Accordingly, the luminances of the first region 110 and the second region 120 can be individually controlled by the first light-emitting layers 11 disposed in the respective regions.

In the light-emitting device 100 illustrated in FIG. 3, the density of the current applied to the first light-emitting layer 11 disposed in the first region (high luminance region) 110 is set higher than the density of the current applied to the first light-emitting layer 11 disposed in the second region (low luminance region) 120. The luminance of the light from the high luminance region 110 can be increased by relatively increasing the density of the current applied to the first light-emitting layer 11 disposed in the high luminance region 110, and the luminance of the light from the low luminance region 120 can be decreased by relatively decreasing the density of the current applied to the first light-emitting layer 11 disposed in the low luminance region 120.

The light-emitting device 100 may include one first light-emitting layer 11. However, in this case, in the light-emitting device 100 including only one first light-emitting layer 11, it is not possible to change the luminance of only a part of the light emitted from the light-emitting device 100 by changing the current value, and thus it is necessary to reduce the luminance of part of the light emitted from the first light-emitting layer 11 by employing, for example, a light adjustment member 30 as illustrated in FIG. 15 described below.

In a case in which the light-emitting device 100 includes only one first light-emitting layer 11, both the first wavelength conversion member 41 and the second wavelength conversion member 42 are disposed on the light extraction surface 11a side of the one first light-emitting layer 11.

As illustrated in FIG. 3, when the boundary between the first wavelength conversion member 41 and the second wavelength conversion member 42 is perpendicular to the light-emitting surface S of the light-emitting device 100, the luminance contrast between the high luminance region 110 and the low luminance region 120 is high, and the difference between the first emission spectrum and the second emission spectrum is clear.

In addition, in the light-emitting device 100 including the plurality of first light-emitting layers 11, when the position of the boundary between the first wavelength conversion member 41 and the second wavelength conversion member 42 is present in the gap between the first light-emitting layers 11 when viewed from the light-emitting surface S side of the light-emitting device 100, the luminance contrast between the high luminance region 110 and the low luminance region 120 is higher, and the difference between the first emission spectrum and the second emission spectrum is clear.

The light-emitting device 100 having such a configuration and arrangement is suitable for a case in which the high luminance region 110 and the low luminance region 120 are to be clearly separated from each other in light distribution of a headlight or the like.

As illustrated in FIG. 3, a first support member 51 having a light-transmissive property can be disposed on the light extraction surface 11a side of the first light-emitting layer 11. The first support member 51 is a substrate that supports the first light-emitting layer 11, and can be a growth substrate when the first light-emitting layer 11 is formed by epitaxial growth.

In general, a light-emitting element may include the first support member 51 and the first light-emitting layer 11 formed on a surface of the first support member 51.

As illustrated in FIG. 3, the light-emitting device 100 can include a light guide member 60 covering the lateral surface of the first support member 51. The light guide member 60 is light-transmissive and guides light from the first light-emitting layer 11 to the first wavelength conversion member 41 or the second wavelength conversion member 42. The light guide member 60 can cover the lateral surface of the first light-emitting layer 11. For example, a light-transmissive resin can be used as the light guide member 60.

In one example, the light guide member 60 has a shape in which the lateral surface is curved in a cross-sectional view. For the shape of the light guide member 60, the lateral surface may be inclined such that the width increases from a lateral surface of the first support member 51 toward the first wavelength conversion member 41 and the second wavelength conversion member 42 in a cross-sectional view. The cross-sectional shape of the lateral surface of the light guide member 60 may be linear or curved.

The light guide member 60 can also function as an adhesive member that bonds the first support member 51 to the first wavelength conversion member 41 and the second wavelength conversion member 42.

As illustrated in FIG. 3, the light-emitting device 100 can further include a light-transmissive member 20 disposed on the light extraction surface 11a side of the first light-emitting layer 11. As the light-transmissive member 20, for example, transparent glass can be used.

In a case in which the light-emitting device 100 includes the light-transmissive member 20, the first wavelength conversion member 41 and the second wavelength conversion member 42 are preferably disposed between the first light-emitting layer 11 and the light-transmissive member 20. That is, the light-transmissive member 20 is preferably not disposed between the first wavelength conversion member 41 and the first light-emitting layer 11 and between the second wavelength conversion member 42 and the first light-emitting layer 11.

The first wavelength conversion member 41 and the second wavelength conversion member 42 contain, for example, a phosphor. The phosphor absorbs a portion of light emitted from the first light-emitting layer 11 and converts the absorbed light into light having a different wavelength, and at this time, the phosphor generates heat. Because the light-transmissive member 20 is not present between the first wavelength conversion member 41 and the first light-emitting layer 11 and between the second wavelength conversion member 42 and the first light-emitting layer 11, heat generated by the phosphors contained in the first wavelength conversion member 41 and the second wavelength conversion member 42 is easily dissipated toward the first light-emitting layer 11. As a result, it is possible to reduce deterioration in the characteristics of the phosphors (change in the wavelength shift amount at the time of wavelength conversion, deterioration of the phosphors) due to heat generation.

In a case in which the first wavelength conversion member 41 and the second wavelength conversion member 42 are disposed between the first light-emitting layer 11 and the light-transmissive member 20, as illustrated in FIG. 3, a surface of the light-transmissive member 20 can serve as the light-emitting surface S of the light-emitting device 100.

When the light-emitting device 100 is mounted on a mounting substrate or the like, the light-emitting surface S of the light-emitting device 100 is usually picked up by suction with a suction jig or the like and the light-emitting device 100 is transported to a mounting position. When the light-emitting surface S of the light-emitting device 100 is the surface of the light-transmissive member 20, the light-emitting surface S of the light-emitting device 100 can be easily picked up with a suction jig or the like.

The light-transmissive member 20 can function as a base material for forming the first wavelength conversion member 41 and the second wavelength conversion member 42. The first wavelength conversion member 41 and the second wavelength conversion member 42 may be formed directly on a surface of the light-transmissive member 20, or may be formed on a surface of the light-transmissive member 20 via an intervening layer (a light-transmissive resin or a light-transmissive inorganic member).

### MODIFIED EXAMPLE

The light-emitting device 200 illustrated in FIG. 4 is different from the light-emitting device 100 according to the first embodiment in that a plurality of support members are included, a plurality of light-transmissive members 20 are included, and a light-reflective member 45 is disposed between the first wavelength conversion member 41 and the second wavelength conversion member 42. These differences will be mainly described.

The other configurations are the same as those of the light-emitting device 100 according to the first embodiment, and accordingly the description thereof will be omitted.

In the light-emitting device 200 illustrated in FIG. 4, the first support member 51 is disposed on the light extraction surface 11a side of the first light-emitting layer 11 disposed in the first region (high luminance region) 110, and the second support member 52 is disposed on the light extraction surface 11a side of the first light-emitting layer 11 disposed in the second region (low luminance region) 120.

The light guide member 60 is disposed between the first support member 51 and the second support member 52, and can function as an adhesive member that bonds the first support member 51 and the second support member 52. The light guide member 60 can also function as, for example, an adhesive member that bonds the first support member 51 and the first wavelength conversion member 41 and bonds the second support member 52 and the second wavelength conversion member 42.

The light-emitting device 200 can include a plurality of light-transmissive members. In the example illustrated in FIG. 4, when viewed from the light-emitting surface S side of the light-emitting device 200, the first light-transmissive member 21 with the first wavelength conversion member 41 is disposed in the high luminance region 110, and the second light-transmissive member 22 with the second wavelength conversion member 42 is disposed in the low luminance region 120. In the example illustrated in FIG. 4, a light-reflective member 45 is disposed between the first light-transmissive member 21 and the second light-transmissive member 22 and between the first wavelength conversion member 41 and the second wavelength conversion member 42.

In the light-emitting device 200 having such a configuration and arrangement, the luminance contrast between the high luminance region 110 and the low luminance region 120 is higher, and the difference between the first emission spectrum and the second emission spectrum is clearer. Therefore, this is suitable for a case in which the high luminance region 110 and the low luminance region 120 are desired to be clearly separated from each other in light distribution of a headlight, or the like.

Instead of the light guide member 60, the light-reflective member 45 may be disposed between the first support member 51 and the second support member 52.

### Method of Manufacturing Light-Emitting Device 100

A method of manufacturing the light-emitting device 100 according to the first embodiment illustrated in FIG. 3 will be described in detail.

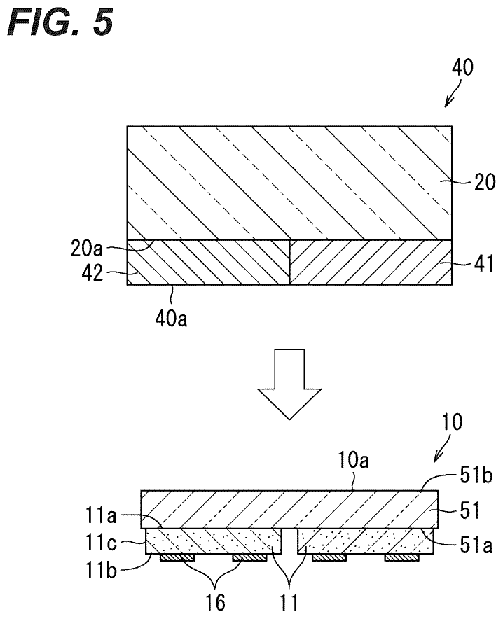

As illustrated in FIG. 5, in the method of manufacturing the light-emitting device 100, the light-emitting element 10 and the wavelength conversion member 40 are provided separately, and then a first surface 10a of the light-emitting element 10 (corresponding to a second surface 51b of the first support member 51) and a first surface 40a of the wavelength conversion member 40 (the surface on which the first wavelength conversion member 41 and the second wavelength conversion member 42 are formed) are caused to face each other and bonded to each other via the light guide member 60.

That is, the method of manufacturing the light-emitting device 100 includes a step of providing the light-emitting element 10, a step of providing the wavelength conversion member 40, and a step of disposing the wavelength conversion member 40 on the light-emitting element 10.

The “light-emitting element 10” includes the first support member 51 and the first light-emitting layer 11 disposed on the first surface 51a of the first support member 51.

The “wavelength conversion member 40” includes the light-transmissive member 20, and the first wavelength conversion member 41 and the second wavelength conversion member 42 disposed on the first surface 20a of the light-transmissive member 20.

### Step of Providing Light-Emitting Element 10

In the step of providing the light-emitting element 10, the light-emitting element 10 including the first support member 51 and the first light-emitting layer 11 is provided. The light-emitting element 10 may be provided by forming the first light-emitting layer 11 on the surface of the first support member 51 to produce the light-emitting element 10, or may be provided by, for example, purchasing the light-emitting element 10 that has already been produced.

### Step of Providing Wavelength Conversion Member 40

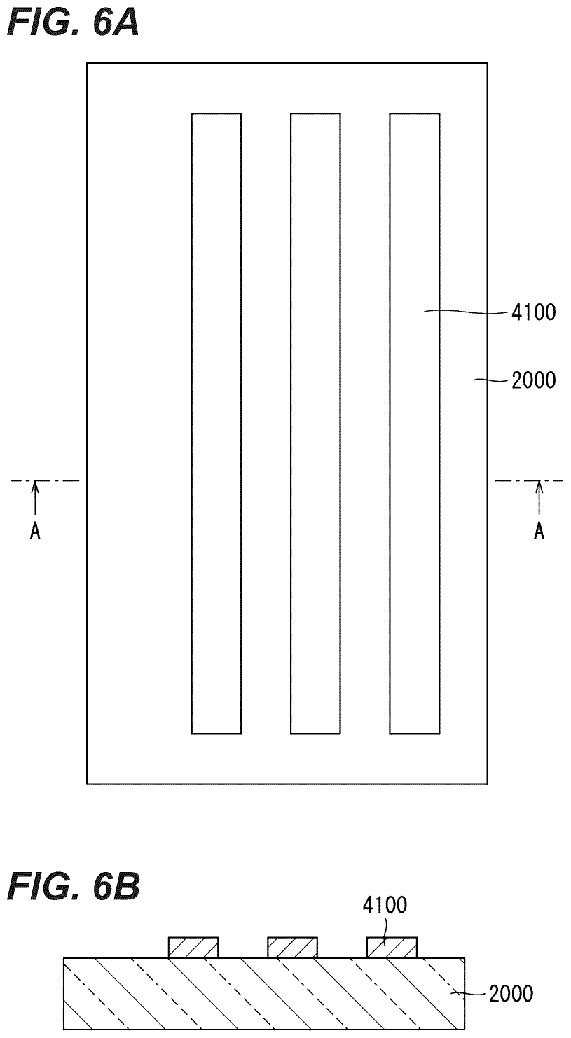

As illustrated in FIGS. 6A and 6B, in the step of providing the wavelength conversion member 40, first, a first wavelength conversion layer 4100 covering a part of the upper surface of a light-transmissive plate 2000 is disposed on the light-transmissive plate 2000 having a flat plate shape. The plan view shape of the first wavelength conversion layer 4100 disposed on the light-transmissive plate 2000 can be any of various shapes such as a stripe shape, a dot shape, an island shape, and a lattice shape. In the example herein, the plurality of first wavelength conversion layers 4100 are disposed in a stripe shape in a plan view. The first wavelength conversion layer 4100 can be formed by printing using a mask.

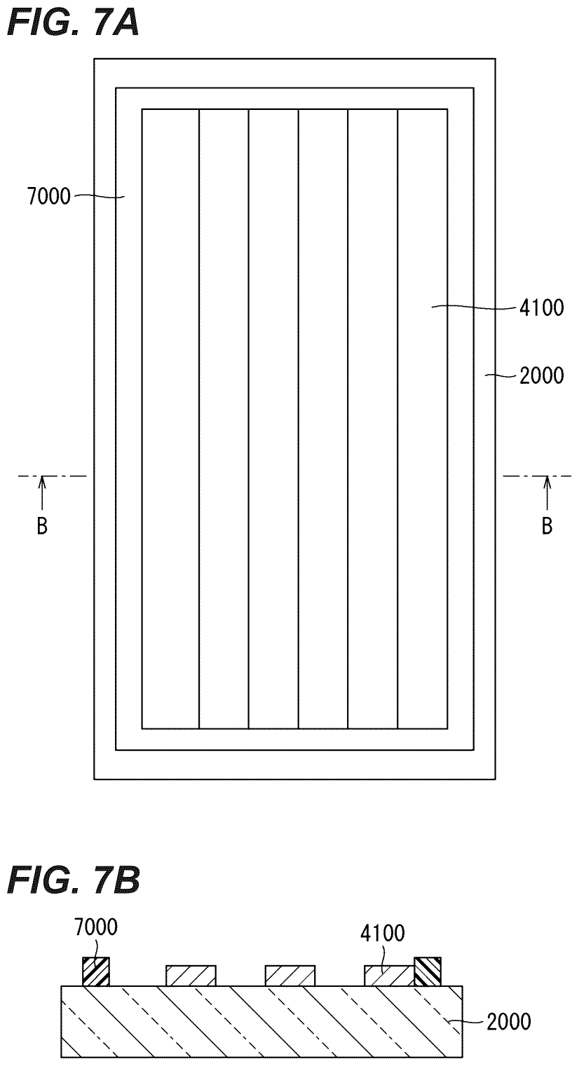

Subsequently, as illustrated in FIGS. 7A and 7B, a frame body 7000 surrounding the first wavelength conversion layer 4100 is formed on the light-transmissive plate 2000 having a flat plate shape. The frame body 7000 may be formed before the first wavelength conversion layer 4100 is formed. The formation of the frame body 7000 may be omitted.

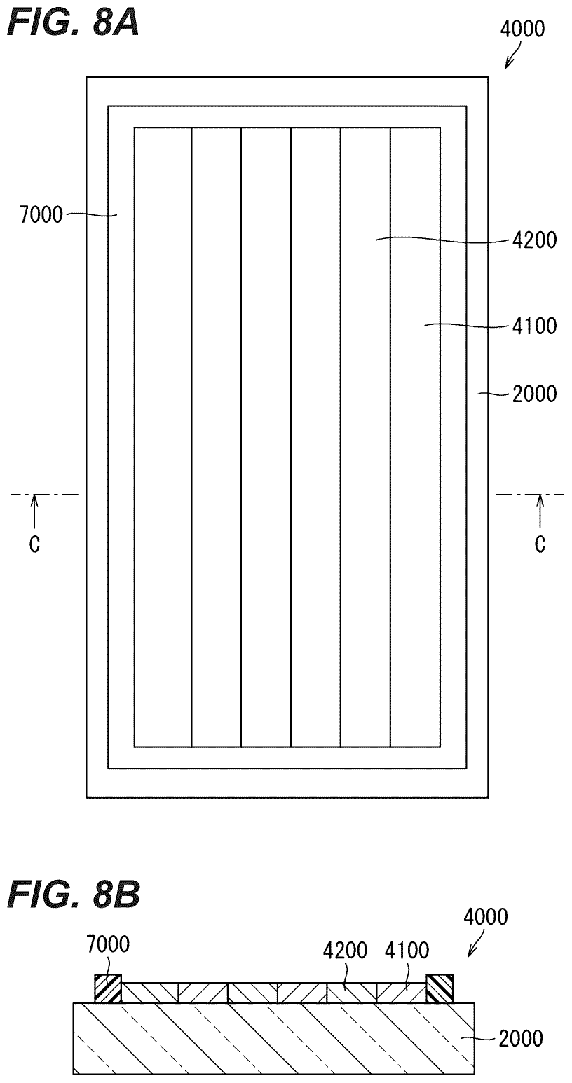

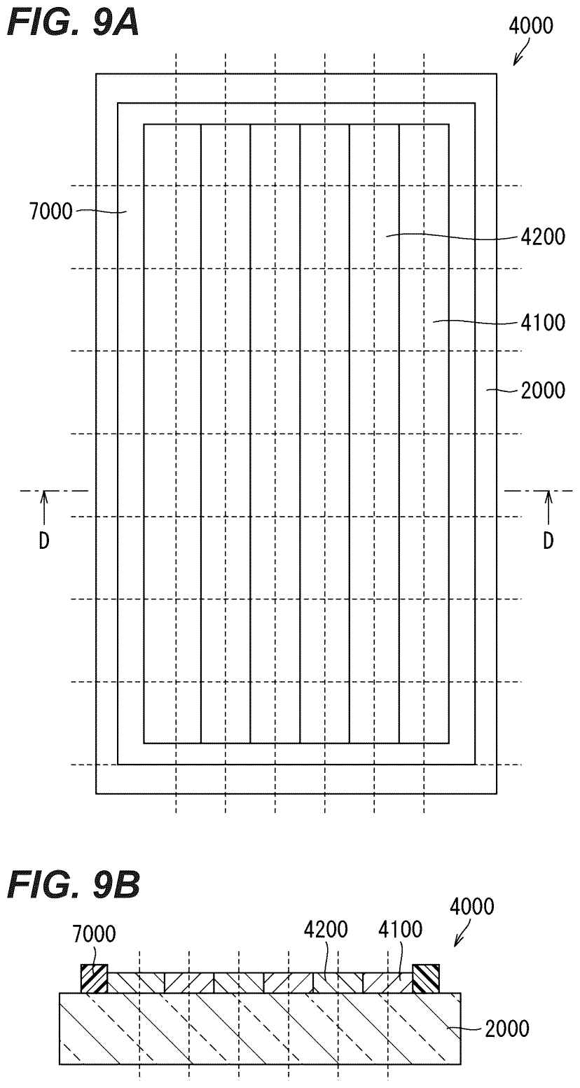

Then, as illustrated in FIGS. 8A and 8B, the second wavelength conversion layer 4200 is disposed on an inner side with respect to the frame body 7000 on the light-transmissive plate 2000 so as to cover surfaces of the light-transmissive plate 2000 that are exposed from the first wavelength conversion layer 4100. In this manner, an intermediate body 4000 of the wavelength conversion member 40 is produced. Then, as illustrated in FIGS. 9A and 9B, the intermediate body 4000 is divided at desired positions to obtain the wavelength conversion members 40. The light-transmissive plate 2000, the first wavelength conversion layer 4100, and the second wavelength conversion layer 4200 before division become the light-transmissive member 20, the first wavelength conversion member 41, and the second wavelength conversion member 42, respectively, after division.

Although an example in which the first wavelength conversion layer 4100 is disposed and then the second wavelength conversion layer 4200 is disposed has been described above, the second wavelength conversion layer 4200 may be disposed before the first wavelength conversion layer 4100 is disposed.

Although a method of simultaneously providing the plurality of wavelength conversion members 40 by dividing the intermediate body 4000 has been described above, the wavelength conversion members 40 may be individually provided. That is, the step of providing the wavelength conversion member 40 may include a step of disposing, on the light-transmissive member 20, the first wavelength conversion member 41 covering a part of the first surface 20a of the light-transmissive member 20, and a step of disposing the second wavelength conversion member 42 covering the light-transmissive member 20 exposed from the first wavelength conversion member 41. Alternatively, the wavelength conversion member 40 may be provided by, for example, purchasing an already-produced wavelength conversion member 40.

Note that either of the step of providing the light-emitting element and the step of providing the wavelength conversion member may be performed earlier than the other, or these steps may be performed in parallel.

### Step of Disposing Wavelength Conversion Member 40 on Light-Emitting Element 10

As illustrated in FIG. 5, the wavelength conversion member 40 is disposed on the first surface 10a of the light-emitting element 10. The wavelength conversion member 40, which includes the first wavelength conversion member 41, the second wavelength conversion member 42, and the light-transmissive member 20 that supports the first wavelength conversion member 41 and the second wavelength conversion member 42, is disposed such that the first surface 40a of the wavelength conversion member 40 is located on a first surface 10a side of the light-emitting element 10 (corresponding to the second surface 51b of the first support member 51 of the light-emitting element 10). At this time, the wavelength conversion member 40 is positioned such that the first light-emitting layer 11 of the light-emitting element 10 and the first wavelength conversion member 41 and the second wavelength conversion member 42 of the wavelength conversion member 40 are in an appropriate positional relationship in a plan view.

The wavelength conversion member 40 is bonded to the first support member 51 using, for example, an adhesive member.

In addition, the light guide member 60 that covers the lateral surfaces of the first support member 51 can be formed of a light-transmissive resin material or the like.

The resin material for forming the light guide member 60 can also be used as an adhesive member. The light guide member 60 can be formed by providing a resin material between the first support member 51 and the wavelength conversion member 40 to bond these members and further extending the resin material to the lateral surfaces of the first support member 51 (FIG. 3). The wavelength conversion member 40 may be bonded to the first support member 51 by a direct bonding method without using an adhesive member.

### Second Embodiment

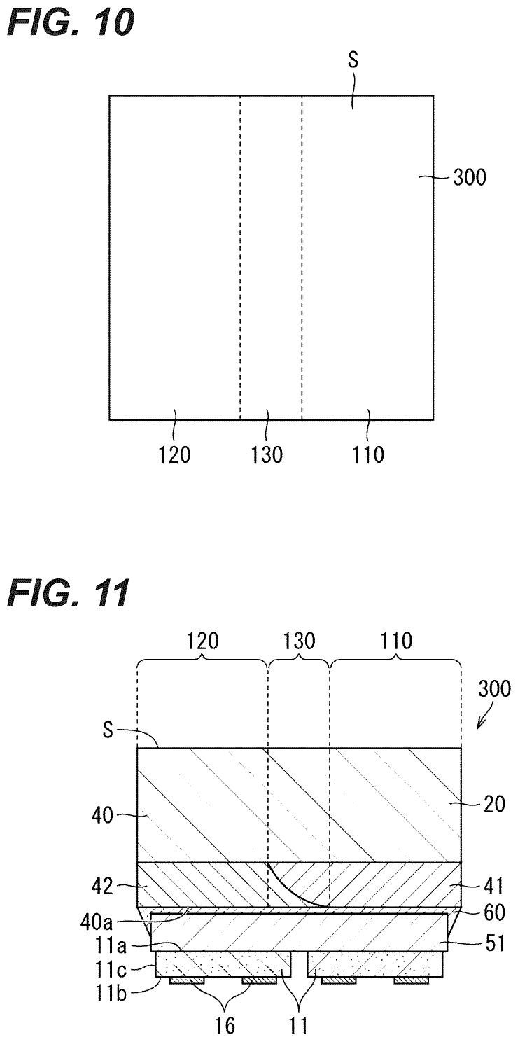

A light-emitting device 300 according to a second embodiment illustrated in FIG. 10 includes a third region 130 between the first region (high luminance region) 110 and the second region (low luminance region) 120 when viewed from the light-emitting surface S of the light-emitting device 300.

Luminance Lc of the third region 130 is equal to or lower than the luminance La of the first region 110 and equal to or higher than the luminance Lb of the second region 120. In the present specification, the third region 130 may be referred to as an “intermediate luminance region 130”.

The intermediate luminance region 130 is located between the low luminance region 120 and the high luminance region 110. The luminance Lc of the intermediate luminance region 130 is equal to or higher than the luminance Lb of the low luminance region 120 and equal to or lower than the luminance La of the high luminance region 110. That is, the intermediate luminance region 130 is a region that emits light having intermediate luminance.

As will be described in detail below, the high luminance region 110 and the low luminance region 120 have a small luminance variation (luminance difference per distance) in each of the regions.

On the other hand, the intermediate luminance region 130 has a large luminance variation in the region.

From a luminance difference ΔLa (cd) obtained by measurement at two points in the high luminance region 110 and a distance Da (μm) between the two points, a luminance variation=ΔLa/Da in the high luminance region 110 (referred to as a “first luminance variation Ha”) is determined.

From a luminance difference ΔLb (cd) obtained by measurement at two points in the low luminance region 120 and a distance Db (μm) between the two points, a luminance variation=ΔLb/Db in the low luminance region 120 (referred to as a “second luminance variation Hb”) is determined.

Similarly, from a luminance difference ΔLc (cd) obtained by measurement at two points in the intermediate luminance region 130 and a distance Dc (μm) between the two points, a luminance variation=ΔLc/Dc in the intermediate luminance region 130 (referred to as a “third luminance variation Hc”) is determined.

The first luminance variation Ha and the second luminance variation Hb are smaller than the third luminance variation Hc.

A specific method of obtaining the first luminance variation Ha, the second luminance variation Hb, and the third luminance variation Hc will be described. First, while moving from the low luminance region 120 through the intermediate luminance region 130 to the high luminance region 110, the luminance of light from each of the regions is measured. Subsequently, the results of the luminance measurement are plotted with the movement distance on the horizontal axis and the luminance on the vertical axis. In the obtained graph, the slope of the graph for the low luminance region 120 is the second luminance variation Hb, the slope of the graph for the intermediate luminance region 130 is the third luminance variation Hc, and the slope of the graph for the high luminance region 110 is the first luminance variation Ha.

In addition, the ranges of the high luminance region 110, the low luminance region 120, and the intermediate luminance region 130 can be specified from this graph.

A region where the slope (luminance variation) of the graph is small and the luminance is low (5% or more and less than 80% of the maximum luminance Laₘₐₓ of the light-emitting device 100) is the low luminance region 120.

The range of a region in which the slope (luminance variation) of the graph is small and the luminance is high (80% or more and 100% or less of the maximum luminance Laₘₐₓ of the light-emitting device 100) is the high luminance region 110.

A region in which the slope (luminance variation) of the graph is large and which has luminance equal to or higher than the luminance Lb of the low luminance region 120 and equal to or lower than the luminance La of the high luminance region 110 is the intermediate luminance region 130. The luminance Lc of the intermediate luminance region 130 is preferably in a range of 10% to 100% of the maximum luminance Laₘₐₓ.

As described above, in the light-emitting device 100 according to the first embodiment, the luminance contrast is high at the boundary between the high luminance region 110 and the low luminance region 120, and the difference between the first emission spectrum and the second emission spectrum is clear.

In contrast, the light-emitting device 300 according to the second embodiment includes the intermediate luminance region 130 between the high luminance region 110 and the low luminance region 120, so that the luminance contrast is low and the emission spectrum gently changes between the high luminance region 110 and the low luminance region 120. The light-emitting device 300 having such a configuration and arrangement is suitable for a case in which a luminance variation between the high luminance region 110 and the low luminance region 120 is desired to be made gentle in light distribution of a headlight, or the like.

The light-emitting device 300 including the intermediate luminance region 130 as illustrated in FIG. 10 can be obtained by, for example, a configuration illustrated in FIG. 11. In the light-emitting device 300 illustrated in FIG. 11, the difference from the light-emitting device 100 illustrated in FIG. 3 will be mainly described below, and the description of the same configuration as that of the light-emitting device 100 will be omitted.

In the light-emitting device 300 illustrated in FIG. 11, when viewed from the light-emitting surface S side of the light-emitting device 300, the intermediate luminance region 130 is arranged in a region where there is a gap between adjacent light-emitting layers 11. Further, in the light-emitting device 300 illustrated in FIG. 11, a part of the first wavelength conversion member 41 and a part of the second wavelength conversion member 42 are disposed in the intermediate luminance region 130 when viewed from the light-emitting surface S side of the light-emitting device 300.

In the example of FIG. 11, when viewed from the light-emitting surface S side of the light-emitting device 300, a part of the first wavelength conversion member 41 and a part of the second wavelength conversion member 42 overlap each other. In a region where the two wavelength conversion members 41 and 42 overlap each other (“overlapping region”), a mixture of light from the high luminance region 110 and light from the low luminance region 120 is emitted. Therefore, the emission spectrum of the light from the overlapping region is an emission spectrum obtained by adding the emission spectrum of the light from the high luminance region 110 (first emission spectrum) and the emission spectrum of the light from the low luminance region 120 (second emission spectrum). The luminance of the light from the overlapping region may be equal to or higher than the luminance Lb of the light from the low luminance region 120 and equal to or lower than the luminance La of the light from the high luminance region 110.

Also in the light-emitting device 100 illustrated in FIG. 3, depending on the luminance difference between the high luminance region 110 and the low luminance region 120 adjacent to each other, a region where there is a gap between the first light-emitting layers 11 adjacent to each other can be the intermediate luminance region 130.

In the overlapping region illustrated in FIG. 11, the boundary between the first wavelength conversion member 41 and the second wavelength conversion member 42 is a curve that is convex downward (the first wavelength conversion member 41 is convex) in a cross-sectional view. However, the overlapping region is not limited to this, and the boundary between the first wavelength conversion member 41 and the second wavelength conversion member 42 may be a straight line or a curved line that is convex upward (the second wavelength conversion member 42 is convex) in a cross-sectional view.

In the example illustrated in FIG. 11, in a cross-sectional view, the width of the first wavelength conversion member 41 (the dimension in a direction parallel to the light-emitting surface S in FIG. 11) increases from the first surface 40a of the wavelength conversion member 40 toward the light-emitting surface S of the light-emitting device 100, whereas the width of the second wavelength conversion member 42 decreases. Alternatively, the width of the first wavelength conversion member 41 may decrease from the first surface 40a of the wavelength conversion member 40 toward the light-emitting surface S of the light-emitting device 100, whereas the width of the second wavelength conversion member 42 may increase.

### MODIFIED EXAMPLES

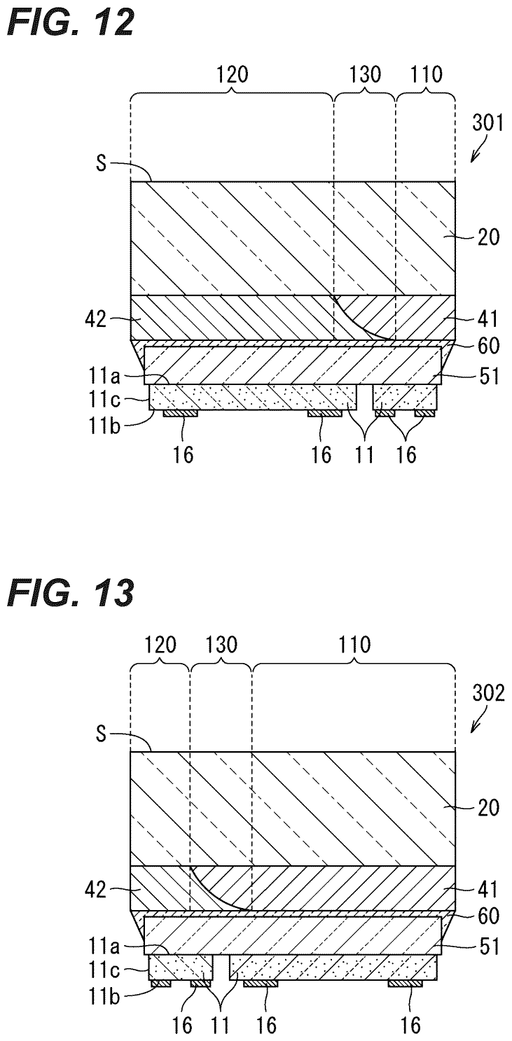

The light-emitting devices illustrated in FIGS. 12 to 14 are modified examples of the light-emitting device 300 according to the second embodiment. The differences between each of these light-emitting devices and the light-emitting device 300 according to the second embodiment will be described. It should be noted that the description of the same configuration as that of the light-emitting device 300 according to the second embodiment will be omitted.

A light-emitting device 301 illustrated in FIG. 12 includes the plurality of first light-emitting layers 11 having different dimensions in a direction parallel to the light-emitting surface S in a cross-sectional view. When the light-emitting device 301 is viewed from the light-emitting surface S side, the first light-emitting layer 11 having a relatively small area is disposed in the first region 110, and the first light-emitting layer 11 having a relatively large area is disposed in the second region 120. That is, the dimension (area) of the first light-emitting layer 11 disposed in the first region 110 is smaller than the dimension (area) of the first light-emitting layer 11 disposed in the second region 120. With this arrangement, when the same amount of current is applied to both of the first light-emitting layers 11, the current density in the first light-emitting layer 11 having a small dimension (small area) is higher than the current density in the first light-emitting layer 11 having a large dimension (large area), so that the luminances of the high luminance region 110 and the low luminance region 120 can be easily adjusted.

In the light-emitting device 301 illustrated in FIG. 12, the dimension (area) of the first light-emitting layer 11 disposed in the first region 110 is smaller than the dimension (area) of the first light-emitting layer 11 disposed in the second region 120. On the other hand, in a light-emitting device 302 illustrated in FIG. 13, the dimension of the first light-emitting layer 11 disposed in the first region 110 is larger than the dimension (area) of the first light-emitting layer 11 disposed in the second region 120. That is, when the light-emitting device 301 is viewed from the light-emitting surface S side, the first light-emitting layer 11 having a relatively large area is disposed in the first region 110, and the first light-emitting layer 11 having a relatively small area is disposed in the second region 120. In the case of such an arrangement, it is necessary to supply different amounts of current to the respective first light-emitting layers 11.

It is necessary to supply a higher current to the first light-emitting layer 11 having a large dimension (large area) disposed in the first region 110, and as a result, the luminous flux of light from the first region 110 can be increased.

A lower current is supplied to the first light-emitting layer 11 having a small dimension (small area) disposed in the second region 120, but the current density is increased, so that the wavelength shift is reduced and the color difference is improved.

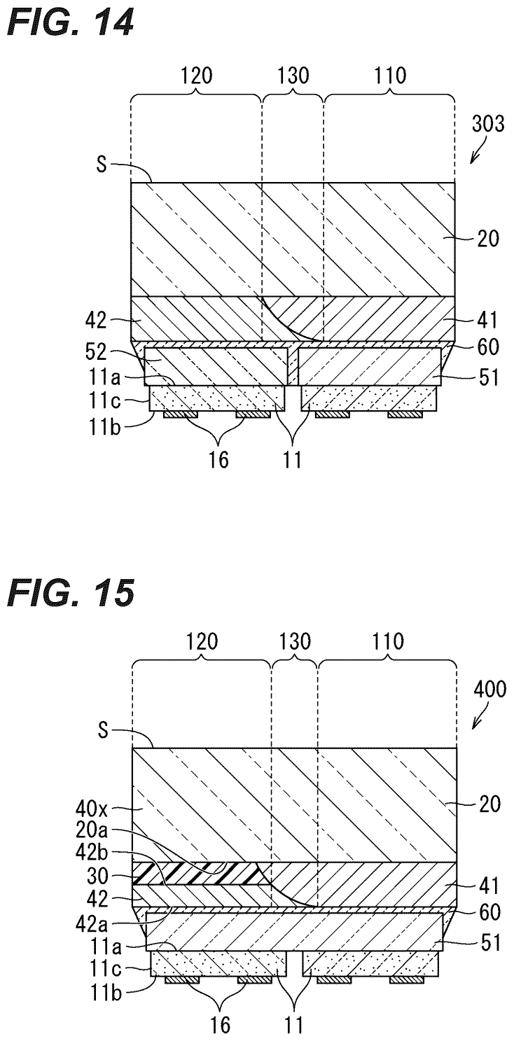

As can be seen from a light-emitting device 303 illustrated in FIG. 14, a plurality of support members 51 and 52 may be included also in the second embodiment.

As in the light-emitting device 200 according to the modified example of the first embodiment (FIG. 4), in the light-emitting device 303 illustrated in FIG. 14, the first support member 51 is disposed on the light extraction surface 11a side of the first light-emitting layer 11 disposed in the first region (high luminance region) 110, and the second support member 52 is disposed on the light extraction surface 11a side of the first light-emitting layer 11 disposed in the second region (low luminance region) 120.

The light-emitting device 303 illustrated in FIG. 14 is different from the light-emitting device 200 illustrated in FIG. 4 in that there is an overlapping region where a part of the first wavelength conversion member 41 and a part of the second wavelength conversion member 42 overlap each other when viewed from the light-emitting surface S side.

### Third Embodiment

A light-emitting device 400 according to a third embodiment illustrated in FIG. 15 further includes the light adjustment member 30 that adjusts the luminance of the light emitted from the second region (low luminance region) 120.

The light adjustment member 30 is disposed on the light extraction surface 11a side of the first light-emitting layer 11, and is disposed over the entire low luminance region 120 when viewed from the light-emitting surface S side of the light-emitting device 400.

The light adjustment member 30 is an optical member having optical characteristics of both light reflectivity and light transmissivity. With the light-emitting device 400 including the light adjustment member 30 disposed in the low luminance region 120, a part of the light from the first light-emitting layer 11 disposed in the low luminance region 120 can be reflected. The light adjustment member 30 can also reflect a part of the light whose wavelength has been converted by the second wavelength conversion member 42.

With the light-emitting device 400 including the light adjustment member 30, the luminance of light from the low luminance region 120 can be reduced without changing the dimension of the first light-emitting layer 11 or the current density applied to the first light-emitting layer 11.

As the light adjustment member 30, a light-reflecting material, a light-transmissive material having a low refractive index, a distributed Bragg reflector (DBR), a wavelength cut filter, or the like can be used.

The light adjustment member 30 is disposed in the low luminance region 120 when viewed from the light-emitting surface S side of the light-emitting device 400. In addition, in a cross-sectional view, the light adjustment member 30 may be disposed at any position as long as it is between the light extraction surface 11a of the first light-emitting layer 11 and the light-emitting surface S of the light-emitting device 400. For example, as illustrated in FIG. 15, the light adjustment member 30 may be disposed between the light-transmissive member 20 and the second wavelength conversion member 42. The concentration of the phosphor contained in the second wavelength conversion member 42 can be reduced, and the reliability is improved by disposing the second wavelength conversion member 42 near the first support member 51.

The light adjustment member 30 may be disposed between the second wavelength conversion member 42 and the first support member 51. The light whose wavelength has been converted by the first wavelength conversion member 41 and the light whose wavelength has been converted by the second wavelength conversion member 42 are less likely to be mixed. Therefore, the light whose wavelength has been converted by the first wavelength conversion member 41 is less likely to be mixed with the light emitted from the low luminance region 120, and the light whose wavelength has been converted by the second wavelength conversion member 42 is less likely to be mixed with the light emitted from the high luminance region 110. Thus, the difference between the emission spectrum of light emitted from the high luminance region 110 (first emission spectrum) and the emission spectrum of light emitted from the low luminance region 120 (second emission spectrum) can be made clear.

In a case in which the light adjustment member 30 is disposed between the second wavelength conversion member 42 and the first support member 51, the light adjustment member 30 may be in contact with either the second wavelength conversion member 42 or the first support member 51, or may be in contact with both the second wavelength conversion member 42 and the first support member 51.

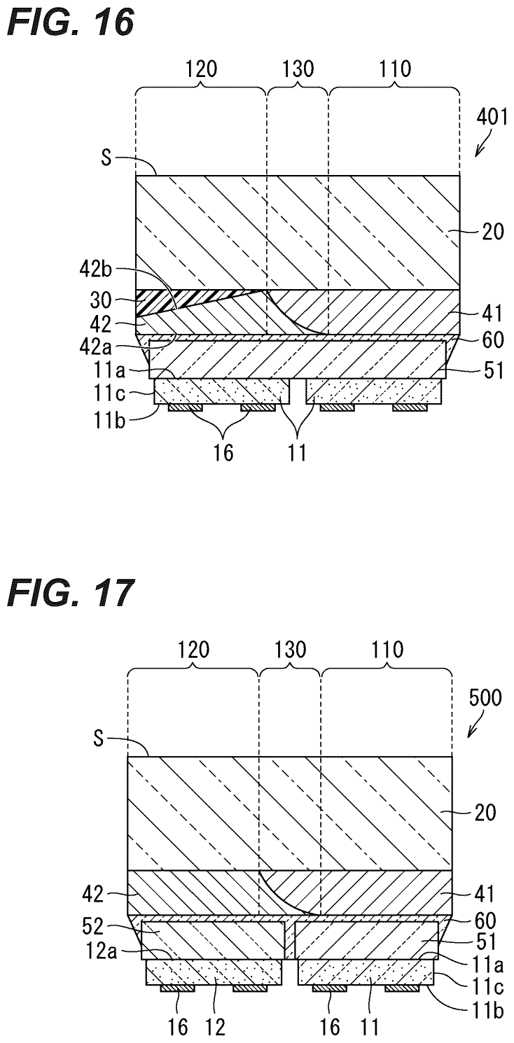

In the light-emitting device 400 illustrated in FIG. 15, the second wavelength conversion member 42 has a first surface 42a facing the first light-emitting layer 11 and a second surface 42b opposite to the first surface 42a. The light adjustment member 30 is disposed on the second surface 42b side of the second wavelength conversion member 42. The surface of the light adjustment member 30 on the second wavelength conversion member 42 side may be flat as illustrated in FIG. 15, or may have a wavy shape. The thickness of the light adjustment member 30 may or may not be uniform. In particular, as in a light-emitting device 401 illustrated in FIG. 16, the thickness is preferably decreased toward the high luminance region 110. In the low luminance region 120, the luminance can be gradually increased toward the intermediate luminance region 130 and the high luminance region 110.

Because the thickness of the second wavelength conversion member 42 is reduced by providing the light adjustment member 30, the amount of material used to form the second wavelength conversion member 42 can be reduced.

### Method of Manufacturing Light-Emitting Device 400

As the light-emitting device 400 includes the light adjustment member 30, the method of manufacturing the light-emitting device 400 includes a step of forming the light adjustment member 30. Other steps are the same as the method of manufacturing the light-emitting device 100 according to the first embodiment.

The method of manufacturing the light-emitting device 400 will be described focusing on the differences from the method of manufacturing the light-emitting device 100 according to the first embodiment.

The method of manufacturing the light-emitting device 400 includes a step of providing the light-emitting element 10, a step of providing a wavelength conversion member 40x (FIG. 15), and a step of disposing the wavelength conversion member 40x on the light-emitting element 10.

As used herein, the “wavelength conversion member 40x” includes the light-transmissive member 20, the first wavelength conversion member 41 and the light adjustment member 30 provided on the first surface 20a of the light-transmissive member 20, and the second wavelength conversion member 42 covering the light adjustment member 30.

### Step of Providing Light-Emitting Element 10

This step is the same as “Step of Providing Light-emitting Element 10” described in the method of manufacturing the light-emitting device 100 according to the first embodiment, and thus the description thereof will be omitted.

### Step of Providing Wavelength Conversion Member 40x

In the step of providing the wavelength conversion member 40x, first, the first wavelength conversion layer 4100 covering a part of the upper surface of the light-transmissive plate 2000 having a flat plate shape is disposed on the light-transmissive plate 2000 as in FIGS. 6A and 6B. However, in FIG. 6B, the cross-sectional shape of the first wavelength conversion layer 4100 is rectangular, but in the case of providing the wavelength conversion member 40x, the first wavelength conversion layer 4100 is formed such that the cross-sectional shape is semi-elliptical, for example, using surface tension.

Subsequently, the frame body 7000 surrounding the first wavelength conversion layer 4100 is formed on the light-transmissive plate 2000 having a flat plate shape as in FIGS. 7A and 7B. The frame body 7000 may be formed before the first wavelength conversion layer 4100 is formed, or the formation of the frame body 7000 may be omitted.

Then, a light adjustment member layer covering the surface of the light-transmissive plate 2000 exposed from the first wavelength conversion layer 4100 is disposed on the inner side with respect to the frame body 7000 on the light-transmissive plate 2000. At this time, the thickness of the light adjustment member layer is made smaller than the thickness of the first wavelength conversion layer 4100.

Finally, the second wavelength conversion layer 4200 covering the light adjustment member layer is disposed. The thickness of the second wavelength conversion layer 4200 is set such that the total thickness of the light adjustment member layer and the second wavelength conversion layer 4200 is substantially equal to the thickness of the first wavelength conversion layer 4100.

In this manner, an intermediate body of the wavelength conversion member 40x is provided.

Then, as in FIGS. 9A and 9B, the intermediate body of the wavelength conversion member 40x is divided at desired positions to obtain the wavelength conversion members 40x. The light-transmissive plate 2000, the first wavelength conversion layer 4100, the second wavelength conversion layer 4200, and the light adjustment member layer before division become the light-transmissive member 20, the first wavelength conversion member 41, the second wavelength conversion member 42, and the light adjustment member 30, respectively, after division.

An example has been described above in which the first wavelength conversion layer 4100 is disposed and then the light adjustment member layer and the second wavelength conversion layer 4200 are disposed, but the first wavelength conversion layer 4100 may be disposed after disposing the light adjustment member layer and the second wavelength conversion layer 4200.

Regarding the arrangement order of the light adjustment member layer and the second wavelength conversion layer 4200, an example in which the light adjustment member layer is disposed first and then the second wavelength conversion layer 4200 covering the light adjustment member layer is disposed has been described above, but the light adjustment member layer covering the second wavelength conversion layer 4200 may be disposed after disposing the second wavelength conversion layer 4200.

Although the method of simultaneously providing a plurality of the wavelength conversion members 40x by dividing the intermediate body of the wavelength conversion member 40x has been described above, the wavelength conversion members 40x may be individually provided. That is, the step of providing the wavelength conversion member 40x may include a step of disposing, on the light-transmissive member 20, the first wavelength conversion member 41 covering a part of the first surface 20a of the light-transmissive member 20, a step of disposing the light adjustment member 30 covering the light-transmissive member 20 exposed from the first wavelength conversion member 41, and a step of disposing the second wavelength conversion member 42 covering the light adjustment member 30. Alternatively, the wavelength conversion member 40x may be provided by, for example, purchasing an already-produced wavelength conversion member 40x.

### Step of Disposing Wavelength Conversion Member 40x on Light-Emitting Element 10

This step is the same as “Step of Disposing Wavelength Conversion Member 40 on Light-emitting Element 10” described in the method of manufacturing the light-emitting device 100 according to the first embodiment except that the wavelength conversion member 40 is replaced with the wavelength conversion member 40x, and thus the description thereof will be omitted.

### Fourth Embodiment

A light-emitting device 500 according to a fourth embodiment illustrated in FIG. 17 is different from the light-emitting device 100 according to the first embodiment in that light-emitting layers having different emission peak wavelengths are disposed in the high luminance region 110 and the low luminance region 120.

The first light-emitting layer 11 has an emission peak in a wavelength range of 400 nm to 500 nm, and the second light-emitting layer 12 has an emission peak at a wavelength longer than that of the emission peak of the first light-emitting layer 11. When viewed from the light-emitting surface S side of the light-emitting device 500, the first light-emitting layer 11 and the first wavelength conversion member 41 are disposed in the first region 110, and the second light-emitting layer 12 and the second wavelength conversion member 42 are disposed in the second region 120. The first wavelength conversion member 41 is disposed on the light extraction surface 11a side of the first light-emitting layer 11 and converts a wavelength of a part of light emitted from the first light-emitting layer 11. The second wavelength conversion member 42 is disposed on the light extraction surface 12a side of the second light-emitting layer 12, and converts a wavelength of a part of light emitted from the second light-emitting layer 12.

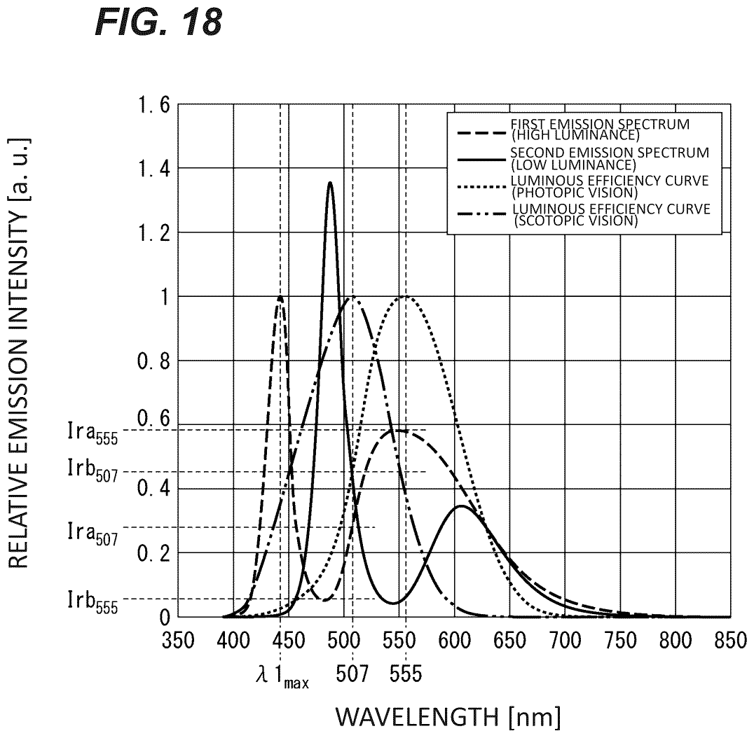

As shown in FIG. 18, since the emission peak wavelength of the second light-emitting layer 12 is shorter than the emission peak wavelength of the first light-emitting layer 11, the light from the second light-emitting layer 12 has a higher scotopic relative luminous efficiency than the light from the first light-emitting layer 11. Accordingly, it is possible to form the light-emitting device 500 in which both the photopic relative luminous efficiency of the light from the high luminance region 110 and the scotopic relative luminous efficiency of the light from the low luminance region 120 are high.

Since the light from the second light-emitting layer 12 has a high scotopic relative luminous efficiency, even if the second wavelength conversion member 42 is omitted, it is possible to form the light-emitting device 500 in which both the photopic relative luminous efficiency of the light from the high luminance region 110 and the scotopic relative luminous efficiency of the light from the low luminance region 120 are high.

As illustrated in FIG. 17, the first support member 51 may be disposed on the light extraction surface 11a side of the first light-emitting layer 11 disposed in the high luminance region 110, and the second support member 52 may be disposed on the light extraction surface 12a side of the second light-emitting layer 12 disposed in the low luminance region 120.

Since the first light-emitting layer 11 and the second light-emitting layer 12 have different emission peak wavelengths, it is preferable to use different support members for the first light-emitting layer 11 and the second light-emitting layer 12.

### Details of Members

Members included in the light-emitting devices according to the first to fourth embodiments will be described in detail.

### First Light-Emitting Layer 11 and Second Light-Emitting Layer 12

The first light-emitting layer 11 and the second light-emitting layer 12 can be formed as semiconductor layered bodies. In the semiconductor layered bodies, for example, a plurality of semiconductor layers (a first semiconductor layer, a semiconductor light-emitting layer, and a second semiconductor layer) are layered on the surfaces of the first support member 51 and the second support member 52. A buffer layer may or may not be disposed between the first support member 51 and the first light-emitting layer 11 and between the second support member 52 and the first light-emitting layer 11.

As the first light-emitting layer 11, a layer that emits light having an emission peak in a wavelength range from 400 nm to 500 nm can be selected. The first light-emitting layer 11 may be, for example, a semiconductor layered body that emits blue-based light (e.g., light with an emission peak wavelength in a range from 430 nm to 500 nm).

As the second light-emitting layer 12, a layer that emits light having an emission peak at a wavelength longer than that of the emission peak of the first light-emitting layer 11 can be selected. The second light-emitting layer 12 may be, for example, a semiconductor layered body that emits blue light (e.g., light with an emission peak wavelength in a range from 430 nm to 500 nm) or green light (e.g., light with an emission peak wavelength in a range from 500 nm to 570 nm).

As the semiconductor layered body, a semiconductor layered body using a nitride-based semiconductor (In_{X}Al_{Y}Ga_{1-X-Y}N, 0≤X, 0≤Y, X+Y≤1), GaP, or the like can be used. In addition to nitride-based semiconductor elements, GaAlAs, AlInGaP, or the like can be used for a semiconductor layered body of one or both of the first light-emitting layer 11 and the second light-emitting layer 12 that emit red light (having a wavelength in a range from 610 nm to 700 nm, for example). As the buffer layer, AlGaN or the like can be used.

In the light-emitting device 100, when the emission intensity of the first light-emitting layer 11 disposed in the high luminance region 110 at the time of light emission is 1, the emission intensity of the light-emitting layer (the first light-emitting layer 11 or the second light-emitting layer 12) disposed in the low luminance region 120 can be greater than or equal to 0.05 and less than or equal to 0.8, preferably greater than or equal to 0.1 and less than or equal to 0.7. By controlling the light emission intensities of the first light-emitting layer 11 and the second light-emitting layer 12 in this manner, the luminance of light from each of the high luminance region 110 and the low luminance region 120 can be controlled within an appropriate range.

### Wavelength Conversion Members 40, 40x

The wavelength conversion member 40 used in the light-emitting devices according to the first, second, and fourth embodiments includes the light-transmissive member 20, and the first wavelength conversion member 41 and the second wavelength conversion member 42 provided on the first surface 20a of the light-transmissive member 20.

The wavelength conversion member 40x used in the light-emitting device according to the third embodiment includes the light-transmissive member 20, the first wavelength conversion member 41 and the light adjustment member 30 provided on the first surface 20a of the light-transmissive member 20, and the second wavelength conversion member 42 covering the light adjustment member 30.

The first wavelength conversion member 41, the second wavelength conversion member 42, the light-transmissive member 20, and the light adjustment member 30 will be described in detail below.

### First Wavelength Conversion Member 41 and Second Wavelength Conversion Member 42

The first wavelength conversion member 41 converts the wavelength of at least part of the light from the first light-emitting layer 11 into a different wavelength. The second wavelength conversion member 42 converts the wavelength of at least a part of light from the first light-emitting layer 11 or the second light-emitting layer 12 into a different wavelength. The first wavelength conversion member 41 and the second wavelength conversion member 42 contain phosphors that absorb light having a certain emission peak wavelength and wavelength-convert the light into light having a different emission peak wavelength.

As the first wavelength conversion member 41 and the second wavelength conversion member 42, a member obtained by mixing and molding a phosphor and a light-transmissive material can be used. For example, as the light-transmissive material, an organic resin material such as an epoxy resin, a silicone resin, a phenol resin, or a polyimide resin, as well as an inorganic material such as glass or a ceramic can be used.

As the phosphor used in the first wavelength conversion member 41, a phosphor that can be excited by the light emitted from the first light-emitting layer 11 is used. As the phosphor used in the second wavelength conversion member 42, a phosphor that can be excited by the light emitted from the first light-emitting layer 11 is used in the first to third embodiments, and a phosphor that can be excited by the light emitted from the second light-emitting layer 12 is used in the fourth embodiment.

Examples of phosphors that can be used for the first wavelength conversion member 41 and the second wavelength conversion member 42 are enumerated below. The phosphors used in the wavelength conversion members 41 and 42 are selected such that the peak wavelength of the light whose wavelength is converted by the first wavelength conversion member 41 is longer than the peak wavelength of the light whose wavelength is converted by the second wavelength conversion member 42.

Examples of a phosphor that emits green light include an yttrium-aluminum-garnet-based phosphor (for example, Y₃(Al,Ga)₅O₁₂:Ce), a lutetium-aluminum-garnet-based phosphor (for example, Lu₃(Al,Ga)₅O₁₂:Ce), a terbium-aluminum-garnet-based phosphor (for example, Tb₃(Al,Ga)₅O₁₂:Ce), a silicate-based phosphor (for example, (Ba,Sr)₂SiO₄:Eu), a chlorosilicate-based phosphor (for example, Ca₈Mg(SiO₄)₄Cl₂:Eu), a β-sialon-based phosphor (for example, Si_{6-z}Al_{z}O_{z}N_{8-z}:Eu (0<z<4.2)), and an SGS-based phosphor (for example, SrGa₂S₄:Eu).

Examples of a phosphor that emits yellow light include an α-sialon-based phosphor (for example, M_{z}(Si,Al)₁₂(O,N)₁₆ (where 0<z≤2, and M is Li, Mg, Ca, Y, and a lanthanide element excluding La and Ce). In addition, the above phosphors that emit green light include a phosphor that emits yellow light. For example, when Y is partially substituted with Gd in the yttrium-aluminum-garnet-based phosphor, an emission peak wavelength can be shifted to a long-wavelength side, and thus, the yttrium-aluminum-garnet-based phosphor can emit yellow light. The above phosphors include a phosphor that can emit orange light.

Examples of a phosphor that emits red light include a nitrogen-containing calcium aluminosilicate (CASN or SCASN)-based phosphor (for example, (Sr,Ca)AlSiN₃:Eu) and a BSESN-based phosphor (for example, (Ba,Sr,Ca)₂Si₅N₈:Eu). Other examples include a manganese-activated fluoride-based phosphor (a phosphor represented by a general formula (I) A₂[M₁₋ₐMnₐF₆] (where, in the general formula (I), A is at least one element selected from the group consisting of K, Li, Na, Rb, Cs, and NH₄, M is at least one element selected from the group consisting of Group 4 elements and Group 14 elements, and a satisfies 0<a<0.2)). Examples of the manganese-activated fluoride-based phosphor include a KSF-based phosphor (for example, K₂SiF₆:Mn), a KSAF-based phosphor (for example, K₂Si_{0.99}Al_{0.01}F_{5.99}:Mn), and an MGF-based phosphor (for example, 3.5MgO 0.5MgF₂ GeO₂:Mn).

For example, an yttrium-aluminum-garnet-based phosphor (for example, (Y,Gd)₃Al₅O₁₂:Ce) in which Y is partially substituted with Gd can be preferably used as a yellow light-emitting phosphor that can emit white mixed-color light in combination with a blue light-emitting element. In the case of the light-emitting device 100 that can emit white light, the types and concentrations of the phosphors contained in the first wavelength conversion member 41 and the second wavelength conversion member 42 are adjusted such that white light of a desired chromaticity rank can be emitted.

The types, particle sizes, and concentrations of the phosphors contained in the first wavelength conversion member 41 and the second wavelength conversion member 42 are determined in consideration of the wavelength conversion efficiencies, the emission wavelengths, and the like of the phosphors to be excited by the light emitted from the first light-emitting layer 11 and the second light-emitting layer 12. The phosphor concentration of each of the first wavelength conversion member 41 and the second wavelength conversion member 42 is preferably, for example, 50 mass % or more and 60 mass % or less. The phosphor concentration indicates the ratio of the phosphor in the first wavelength conversion member 41 or the second wavelength conversion member 42 containing the phosphor.

### Light-Transmissive Member 20

Examples of the light-transmissive member 20 include those obtained by molding a light-transmissive material such as a resin, glass, or an inorganic substance into a plate shape. The light-transmissive member 20 has an area equivalent to the total area of the first wavelength conversion member 41 and the second wavelength conversion member 42 in a plan view. Examples of the glass include borosilicate glass and quartz glass, and examples of the resin include a silicone resin and an epoxy resin. Among these, glass is preferably used for the light-transmissive member 20 in consideration of resistance to deterioration by light, mechanical strength, and the like.

The light-transmissive member 20 is a member for supporting the first wavelength conversion member 41 and the second wavelength conversion member 42 in the wavelength conversion member 40. The first wavelength conversion member 41 and the second wavelength conversion member 42 are disposed on the surface of the light-transmissive member 20 made of a glass plate, for example, by printing or the like. With such a configuration, the first wavelength conversion member 41 and the second wavelength conversion member 42 can be made thinner. As a result, the optical path length of light passing through the first wavelength conversion member 41 and the second wavelength conversion member 42 is shortened, and attenuation of light when passing through the first wavelength conversion member 41 and the second wavelength conversion member 42 is suppressed, so that a light-emitting device with higher luminance can be obtained.

The thickness of the light-transmissive member 20 can be, for example, 30 μm or more and 300 μm or less, and preferably 60 μm or more and 200 μm or less, in consideration of downsizing of the light-emitting device, the mechanical strengths of the first wavelength conversion member 41 and the second wavelength conversion member 42, and the like.

The light-transmissive member 20 can contain a light diffusion member. The light diffusion member contained in the light-transmissive member 20 can reduce chromaticity unevenness and luminance unevenness. Examples of the light diffusion member include titanium oxide, barium titanate, aluminum oxide, and silicon oxide.

### Light Adjustment Member 30

As the light adjustment member 30, a light-reflecting material, a light-transmissive material having a low refractive index, a distributed Bragg reflector (DBR), a wavelength cut filter, or the like can be used.

As the light reflective material, a material obtained by mixing and molding a resin and a light-reflecting substance can be used. Examples of the resin include a resin containing at least one of a silicone resin, a modified silicone resin, an epoxy resin, a modified epoxy resin, an acrylic resin, a phenol resin, a bismaleimide triazine resin, and a polyphthalamide resin, and a hybrid resin thereof. Among these materials, it is preferable to use a resin containing, as a base polymer, a silicone resin, which exhibits a good heat resistance property and electrically insulating property and has flexibility. Examples of the light-reflecting substance include titanium oxide, silicon oxide, zirconium oxide, magnesium oxide, calcium carbonate, calcium hydroxide, calcium silicate, zinc oxide, barium titanate, potassium titanate, aluminum oxide, aluminum nitride, boron nitride, and mullite, and a combination thereof. Among these materials, titanium oxide is preferable because it is relatively stable with respect to moisture or the like and has a high refractive index.

### Light Guide Member 60

For example, a light-transmissive resin can be used as the light guide member 60. As the light-transmissive resin, for example, an organic resin such as an epoxy resin, a silicone resin, a phenol resin, or a polyimide resin can be used. In particular, a silicone resin, which has a high heat resistance, is preferably used. In addition, the above-described light diffusion member may or may not be contained.

### First Support Member 51 and Second Support Member 52

Examples of the first support member 51 and the second support member 52 include an insulating substrate made of sapphire or spinel (MgAl₂O₄), and a nitride-based semiconductor substrate made of InN, AlN, GaN, InGaN, AlGaN, or InGaAlN. In order to extract light emitted from the first light-emitting layer 11 through the first support member 51, the first support member 51 is preferably formed using a light-transmissive material.

### EXAMPLES

### First Example

The light-emitting device 100 illustrated in FIG. 3 was fabricated. Table 1 shows the emission peak wavelength of the light-emitting layer used and the types of the phosphors contained in the first wavelength conversion member 41 and the second wavelength conversion member 42.

In each of the high luminance region 110 and the low luminance region 120, one first light-emitting layer 11 having the same dimension when viewed from the light-emitting surface S (the area of the light extraction surface 11a) was disposed. The low luminance region 120 was masked, and the emission spectrum (first emission spectrum) of light emitted from the high luminance region 110 was measured. Subsequently, the high luminance region 110 was masked, and an emission spectrum (second emission spectrum) of light emitted from the low luminance region 120 was measured. FIG. 2 shows a first emission spectrum and a second emission spectrum of the light-emitting device 100 according to the first example.

With respect to the maximum intensity Iaₘₐₓ in a wavelength range from 400 nm to 500 nm of the first emission spectrum, the relative intensities Ia₅₀₇ and Ia₅₅₅ at a wavelength of 507 nm and a wavelength of 555 nm of the first emission spectrum and the relative intensities Ib₅₀₇ and Ib₅₅₅ at a wavelength of 507 nm and a wavelength of 555 nm of the second emission spectrum were obtained and shown in Table 1.

TABLE 1

| | | LOW LUMINANCE | HIGH LUMINANCE |
|---|---|---|---|
| | | REGION 120 | REGION 110 |
| LIGHT- | TYPE | FIRST LIGHT- | FIRST LIGHT- |
| EMITTING | | EMITTING LAYER 11 | EMITTING LAYER 11 |
| LAYER | EMISSION PEAK | 450 nm | 450 nm |
| | WAVELENGTH | | |
| WAVELENGTH CONVERSION | | SECOND | FIRST WAVELENGTH |
| MEMBER | | WAVELENGTH | CONVERSION |
| | | CONVERSION | MEMBER 41 |
| | | MEMBER 42 | |
| PHOSPHOR | YELLOW | G-YAG/G-LAG | YAG |
| CONTAINED | PHOSPHOR | 520 nm | 550 nm |
| IN | EMISSION PEAK | | |
| WAVELENGTH | WAVELENGTH | | |
| CONVERSION | RED PHOSPHOR | BSESN/SCASN | — |
| MEMBER | EMISSION PEAK | 610 nm | |
| | WAVELENGTH | | |
| RELATIVE | 507 nm | 0.369 | 0.272 |
| INTENSITY | 555 nm | 0.435 | 0.580 |

### Second Example

The light-emitting device 500 illustrated in FIG. 17 was fabricated. Table 2 shows the emission peak wavelengths of the light-emitting layers used and the types of the phosphors contained in the first wavelength conversion member 41 and the second wavelength conversion member 42.

Note that the first light-emitting layer 11 was disposed in the high luminance region 110, and the second light-emitting layer 12 was disposed in the low luminance region 120. The first light-emitting layer 11 and the second light-emitting layer 12 had the same dimensions when viewed from the light-emitting surface S (the areas of the light extraction surfaces 11a and 12a).

As in the first example, the first emission spectrum and the second emission spectrum were measured. FIG. 18 shows the first emission spectrum and the second emission spectrum of the light-emitting device 500 according to a second example.

With respect to the maximum intensity Iaₘₐₓ in a wavelength range from 400 nm to 500 nm of the first emission spectrum, the relative intensities Ia₅₀₇ and Ia₅₅₅ at a wavelength of 507 nm and a wavelength of 555 nm of the first emission spectrum and the relative intensities Ib₅₀₇ and Ib₅₅₅ at a wavelength of 507 nm and a wavelength of 555 nm of the second emission spectrum were obtained and shown in Table 2.

TABLE 2

| | | LOW LUMINANCE | HIGH LUMINANCE |
|---|---|---|---|
| | | REGION 120 | REGION 110 |
| LIGHT- | TYPE | SECOND LIGHT- | FIRST LIGHT- |
| EMITTING | | EMITTING LAYER 12 | EMITTING LAYER 11 |
| LAYER | EMISSION PEAK | 490 nm | 450 nm |
| | WAVELENGTH | | |
| WAVELENGTH CONVERSION | | SECOND | FIRST WAVELENGTH |
| MEMBER | | WAVELENGTH | CONVERSION |
| | | CONVERSION | MEMBER 41 |
| | | MEMBER 42 | |
| PHOSPHOR | YELLOW | YAG | YAG |
| CONTAINED | PHOSPHOR | 550 nm | 550 nm |
| IN | EMISSION PEAK | | |
| WAVELENGTH | WAVELENGTH | | |
| CONVERSION | RED PHOSPHOR | BSESN/SCASN | — |
| MEMBER | EMISSION PEAK | 610 nm | |
| | WAVELENGTH | | |
| RELATIVE | 507 nm | 0.461 | 0.272 |
| INTENSITY | 555 nm | 0.058 | 0.580 |

The light-emitting devices according to the embodiments of the present disclosure can be preferably utilized for vehicle lighting such as headlights. In addition, the light-emitting devices according to the embodiments of the present disclosure can be utilized for the light source for a backlight of a liquid crystal display, various types of lighting fixtures, a large display, various types of display devices for advertisements, destination information, and the like, and further, a digital video camera, image reading devices in a facsimile, a copy machine, a scanner, and the like, and a projector device, for example.

What is claimed is:

1. A light-emitting device comprising:
a first region configured to emit light with luminance La when the light-emitting device is turned on; and
a second region configured to emit light with luminance Lb when the light-emitting device is turned on, wherein
the luminance La of the first region is higher than the luminance Lb of the second region,
an emission spectrum of the light emitted from the first region has
a maximum intensity Iaₘₐₓ in a wavelength range of 400 nm to 500 nm,
an intensity Ia₅₀₇ at a wavelength of 507 nm, and
an intensity Ia₅₅₅ at a wavelength of 555 nm,
an emission spectrum of the light emitted from the second region has
an intensity Ib₅₀₇ at a wavelength of 507 nm, and
an intensity Ib₅₅₅ at a wavelength of 555 nm,
relative intensities Ira₅₀₇, Ira₅₅₅, Irb₅₀₇, and Irb₅₅₅ are obtained by respectively dividing the intensities Ia₅₀₇, Ia₅₅₅, Ib₅₀₇, and Ib₅₅₅ by the maximum intensity Iaₘₐₓ,
the relative intensity Ira₅₀₇ is lower than the relative intensity Irb₅₀₇, and
the relative intensity Ira₅₅₅ is higher than the relative intensity Irb₅₅₅.

2. The light-emitting device according to claim 1, further comprising:
at least one first light-emitting layer having an emission peak in a wavelength range of 400 nm to 500 nm; and
at least two wavelength conversion members disposed on a light extraction surface side of the at least one first light-emitting layer and configured to convert a wavelength of light emitted from the at least one first light-emitting layer, the at least two wavelength conversion members including a first wavelength conversion member and a second wavelength conversion member, wherein
when viewed from a light-emitting surface side of the light-emitting device,
the first wavelength conversion member is disposed in the first region, and
the second wavelength conversion member is disposed in the second region, and
a peak wavelength of light whose wavelength is converted by the first wavelength conversion member is longer than a peak wavelength of light whose wavelength is converted by the second wavelength conversion member.

3. The light-emitting device according to claim 2, further comprising
a plurality of first light-emitting layers including the at least one first light-emitting layer, wherein
when viewed from the light-emitting surface side of the light-emitting device, each of the first region and the second region includes at least one of the first light-emitting layers.

4. The light-emitting device according to claim 3, wherein
a density of a current applied to one of the first light-emitting layers that is disposed in the first region is higher than a density of a current applied to one of the first light-emitting layers that is disposed in the second region.

5. The light-emitting device according to claim 2, further comprising
a light adjustment member configured to adjust the luminance Lb of the light emitted from the second region, wherein
the light adjustment member is disposed on the light extraction surface side of the at least one first light-emitting layer, and is disposed over a whole of the second region when viewed from the light-emitting surface side of the light-emitting device.

6. The light-emitting device according to claim 5, wherein
the second wavelength conversion member has a first surface facing the at least one first light-emitting layer and a second surface opposite to the first surface, and
the light adjustment member is disposed on a side of the second surface of the second wavelength conversion member.

7. The light-emitting device according to claim 1, further comprising
a third region between the first region and the second region when viewed from the light-emitting surface side of the light-emitting device, wherein
the third region has luminance Lc equal to or higher than the luminance Lb and equal to or lower than the luminance La.

8. The light-emitting device according to claim 2, further comprising
a third region between the first region and the second region when viewed from the light-emitting surface side of the light-emitting device, wherein
the third region has luminance Lc equal to or higher than the luminance Lb and equal to or lower than the luminance La, and
a part of the first wavelength conversion member and a part of the second wavelength conversion member are located in the third region when viewed from the light-emitting surface side of the light-emitting device.

9. The light-emitting device according to claim 1, further comprising:
a first light-emitting layer having an emission peak in a wavelength range of 400 nm to 500 nm;
a second light-emitting layer having an emission peak at a wavelength longer than a wavelength of an emission peak of the first light-emitting layer; and
a first wavelength conversion member disposed on a light extraction surface side of the first light-emitting layer and configured to convert a wavelength of light emitted from the first light-emitting layer, wherein
when viewed from a light-emitting surface side of the light-emitting device,
the first light-emitting layer and the first wavelength conversion member are disposed in the first region, and
the second light-emitting layer is disposed in the second region.

10. The light-emitting device according to claim 9, further comprising
a second wavelength conversion member disposed on a light extraction surface side of the second light-emitting layer and configured to convert a wavelength of light emitted from the second light-emitting layer.

11. The light-emitting device according to claim 2, further comprising
a light-transmissive member disposed on the light extraction surface side of the first light-emitting layer, wherein
the first wavelength conversion member and the second wavelength conversion member are disposed between the first light-emitting layer and the light-transmissive member.

12. The light-emitting device according to claim 9, further comprising
a light-transmissive member disposed on the light extraction surface side of the first light-emitting layer, wherein
the first wavelength conversion member is disposed between the first light-emitting layer and the light-transmissive member.
